(19) United States
(12) Patent Application Publication
(10) Pub. No.: US 2007/0114855 A1
(43) Pub. Date: May 24, 2007

(54) Actuator

(75) Inventor: Toshio Chamura, Tokyo (JP)

Correspondence Address: OLIFF & BERRIDGE, PLC, P.O. BOX 19928, ALEXANDRIA, VA, 22320, US

(73) Assignee: TDK Corporation, Tokyo (JP)

(21) Appl. No.: 10/582,159

(22) PCT Filed: Dec. 3, 2004
(86) PCT No.: PCT/JP04/18049

§ 371 Date: Jun. 8, 2006

(30) Foreign Application Priority Data
Dec. 18, 2003 (JP) 2993-420401

(51) Int. Cl. H01L 41/00

(52) U.S. Cl. 310/26

(57) ABSTRACT

An actuator has a columnar magnetostrictor 51, a drive coil 54, and an elastic member (sponges 52a, 52b). The columnar magnetostrictor 51 has one end defined as a fixed end and the other end defined as a free end to expand and contract along an axial direction; the drive coil 54 is arranged to generate a magnetic field to expand and contract the columnar magnetostrictor 51 by a drive current; the elastic member (sponges 52a, 52b) is disposed on each of two end faces of the columnar magnetostrictor 51; an object (plate body 7) can be actuated with expansion and contraction of the columnar magnetostrictor 51.

### TECHNICAL FIELD

The present invention relates to an actuator using a magnetostrictor.

### BACKGROUND ART

An example of the known actuators of this type is the one disclosed in Patent Document 1 below. This actuator has a columnar magnetostrictor, and a drive coil wound on a bobbin around the columnar magnetostrictor. In this case, the columnar magnetostrictor is so arranged that one end face is in contact with a disc magnetic body and that the other end face is in contact with an end face of a magnetic member. In this case, the magnetic member is provided with a flange, and an elastic member is interposed between this flange and a case. Therefore, the magnetic member is biased toward the columnar magnetostrictor by the interposed elastic member, so as to be maintained in a state in which it can freely travel back and forth in the directions along the vibrating directions of the columnar magnetostrictor. In consequence, the disc magnetic body, the columnar magnetostrictor, and the magnetic member are integrally coupled so as to permit vibration of the columnar magnetostrictor.

In this actuator, when a drive current based on an input signal is supplied, the drive coil generates a magnetic field oriented along the axial direction of the columnar magnetostrictor. On this occasion, the columnar magnetostrictor expands and contracts in the axial direction of the columnar magnetostrictor as the generated magnetic field is applied thereto. For this reason, the magnetic member vibrates in the axial direction of the columnar magnetostrictor in accordance with the expansion and contraction of the columnar magnetostrictor. Therefore, when this magnetic member is urged against a vibrator such as a diaphram, the vibration of the magnetic member is transmitted to the vibrator.

Patent Document 1: Japanese Patent Application Laid-Open Gazette No. 9-261797 (page 3, FIG. 1)

### DISCLOSURE OF THE INVENTION

### Problem to be Solved by the Invention

However, this actuator has the following problem. Namely, in this actuator the columnar magnetostrictor is made of a material that can break (crack). In addition, the columnar magnetostrictor has such a property that with application of a magnetic field along the axial direction, displacement with expansion and contraction in the part near the edge of the end face of the columnar magnetostrictor is greater than displacement with expansion and contraction in the central part. Therefore, even if the columnar magnetostrictor is formed with flat end faces at the both ends thereof, the two end faces are deformed into such a conical shape that the central part has an invisibly small depression, upon expansion of the columnar magnetostrictor with application of the magnetic field. On this occasion, the columnar magnetostrictor comes into contact only in the edge of the end faces of the columnar magnetostrictor with each end face of the disc magnetic body and the magnetic member. Therefore, the stress due to the expansion of the columnar magnetostrictor is concentrated at the edge of the end faces of the columnar magnetostrictor. In consequence, this actuator has a risk that the edge of the end faces can crack and break because of repetitions of the stress concentration after long-term use. If a foreign body such as dust is attached to an end face of the columnar magnetostrictor, the stress due to expansion of the columnar magnetostrictor could also be concentrated on the part to which the foreign body is attached, so as to break the columnar magnetostrictor. Furthermore, the columnar magnetostrictor could also break with application of an external force due to a drop or the like to an end face. Moreover, there is fine unevenness in the end faces of the columnar magnetostrictor and the stress is likely to be concentrated on this unevenness, in the same manner as the stress is concentrated on the part where the foreign body is attached, so as to be one of the causes of breakage.

The present invention has been accomplished in view of the problem to be solved and a principal object of the invention is to provide an actuator capable of avoiding the breakage of the columnar magnetostrictor.

### Means for Solving the Problem

In order to achieve the above object, an actuator according to the present invention comprises a columnar magnetostrictor one end of which is defined as a fixed end and an other end of which is defined as a free end to expand and contract along an axial direction; a magnetic field generator for generating a magnetic field to expand and contract the columnar magnetostrictor by a drive current; and an elastic member disposed on at least one end face of the columnar magnetostrictor, the actuator being arranged to be able to actuate an object with expansion and contraction of the columnar magnetostrictor.

In this case, preferably, the elastic member is disposed on each of two end faces of the columnar magnetostrictor.

### EFFECT OF THE INVENTION

In the actuator according to the present invention, the elastic member is disposed on at least one end face of the columnar magnetostrictor, whereby the elastic member absorbs stress applied to the end face of the columnar magnetostrictor. With this actuator, therefore, it is feasible to avoid occurrence of breakage of the columnar magnetostrictor due to the concentration of stress on the edge of the end face of the columnar magnetostrictor, the concentration of stress on the end face of the columnar magnetostrictor due to attachment of a foreign body, and the concentration of an external force on the end face due to a drop or the like. Even if breakage occurs, the degree of the breakage can be reduced.

In the actuator according to the present invention, the elastic member is disposed on each of the two end faces of the columnar magnetostrictor, whereby it is feasible to more effectively avoid the breakage of the columnar magnetostrictor due to the stress and external force on the columnar magnetostrictor. Even if breakage occurs, the degree of the breakage can be further reduced.

### BRIEF DESCRIPTION OF THE DRAWINGS

FIG. 1 is a sectional view showing a configuration of pencil type speaker 1.

FIG. 2 is a block diagram showing an electric circuit of pencil type speaker 1.

### DESCRIPTION OF REFERENCE SYMBOLS

1: pencil type speaker; 22: partition; 51: columnar magnetostrictor; 54: drive coil; 55: vibration transmitter; 52a, 52b: sponges.

### BEST MODES FOR CARRYING OUT THE INVENTION

The best mode of the actuator according to the present invention will be described below with reference to the accompanying drawings.

First, a configuration of pencil type speaker 1 to which the actuator according to the present invention is applied, will be described with reference to the drawings.

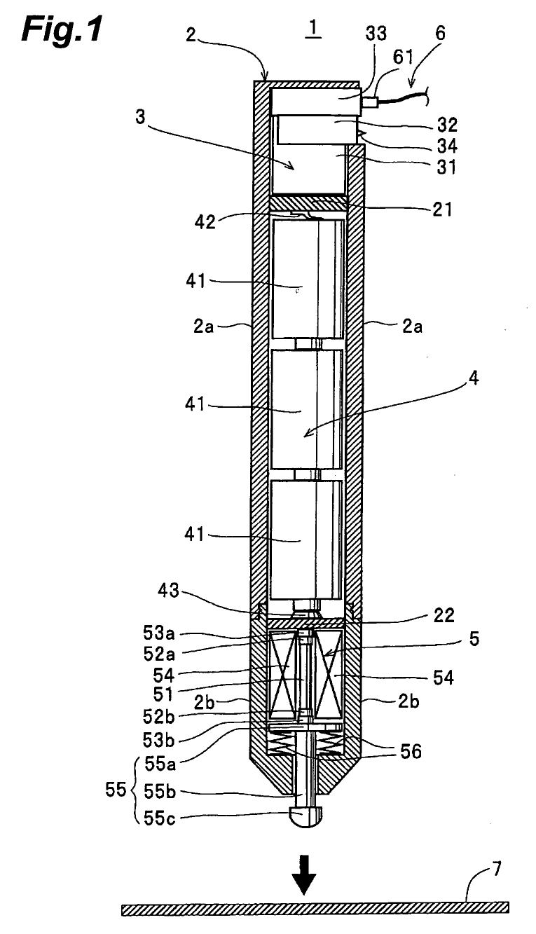

The pencil type speaker 1, as shown in FIG. 1, has a cylindrical housing 2, an acoustic signal amplifier 3, a power supply 4, and a vibration transducer 5, and is arranged to be able to output an acoustic signal when the tip of the pencil type speaker 1 is urged, for example, against a plate 7 as a vibrator. The housing 2, as shown in the same figure, is constructed with an upper housing body 2a and a lower housing body 2b each made of synthetic resin, and the two housing bodies 2a, 2b are integrally coupled through engagement between engaging parts formed at end portions thereof, thereby forming an elongated pencil shape as a whole. The upper housing body 2a is provided with a partition 21, the acoustic signal amplifier 3 is housed in an interior space on the rear end side partitioned by this partition 21, and the power supply 4 is housed in an interior space on the tip end side partitioned by the partition 21. On the other hand, another partition 22 for separating the power supply 4 from the vibration transducer 5 is fixed to the lower housing body 2b.

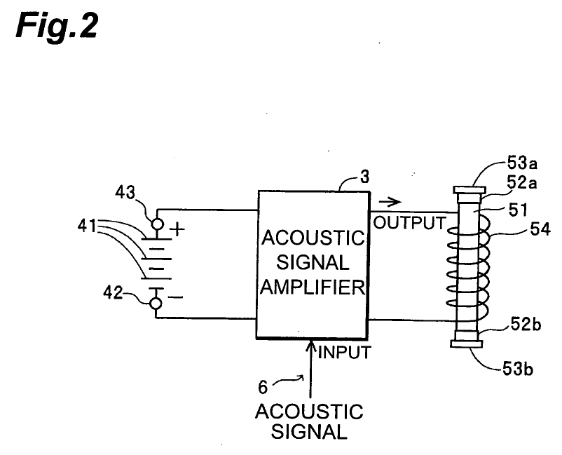

The acoustic signal amplifier 3, as shown in FIG. 2, amplifies an acoustic signal fed through an acoustic signal cable 6 from the outside and outputs a drive current generated, through an unrepresented connection cable to a drive coil 54. The acoustic signal amplifier 3, as shown in FIG. 1, is provided with an amplifier substrate 31 disposed on the rear end side of the upper housing body 2a, and a power switch 32 and an acoustic signal input connector 33 are mounted, as shown in the same figure, on this amplifier substrate 31. In this case, the power switch 32, as shown in the same figure, is provided with a knob 34 permitting a user to turn on and off the pencil type speaker 1 through switching operation. The acoustic signal input connector 33, as shown in the same figure, is constructed as a jack into which a plug 61 of the acoustic signal cable 6 for input of the acoustic signal from the outside can be inserted.

The power supply 4, as shown in FIGS. 1 and 2, is constructed as an example with three dry batteries 41, 41, 41, a battery terminal 42 fixed to the partition 21, and a battery terminal 43 fixed to the partition 22, and supplies power to the acoustic signal amplifier 3 through connection cables connected to the battery terminals 42, 43. In this case, the dry batteries 41 are taken in and out through an opening at the distal end of the upper housing body 2a in a state in which the upper housing body 2a is separated from the lower housing body 2b as the engaging parts are disengaged from each other.

The vibration transducer 5 is disposed in the interior space of the lower housing body 2b and, as shown in FIGS. 1 and 2, is constructed with a columnar magnetostrictor 51, sponges 52a, 52b, bias magnets 53a, 53b, a drive coil 54, a vibration transmitter 55, and, for example, four springs 56. The columnar magnetostrictor 51 functions as an element that expands and contracts in the axial direction with application of a magnetic field in a direction along the axial direction, to convert a variation of the magnetic field into mechanical vibration. The columnar magnetostrictor 51 is made, for example, of a giant magnetostrictive material having the central composition of Th0.34-Dy0.66-Fe1.90, which produces a large displacement of approximately not less than 1500 ppm nor more than 2000 ppm in the axial direction in a magnetic field. One end of the columnar magnetostrictor 51 on the partition 22 side corresponds to the fixed end in the present invention, and the other end on the vibration transmitter 55 side corresponds to the free end in the present invention.

The sponges 52a, 52b correspond to the elastic member in the present invention and function as elastic bodies before application of a predetermined pressure. On the other hand, when an external force over the predetermined pressure is applied, the sponges 52a, 52b seldom function as elastic bodies, but they function as inelastic plate bodies that transmit vibration and that have such hardness as to absorb stress concentrated on the end faces. In this case, the sponge 52a is disposed in a state in which one end face of the sponge 52a is in contact with the end face of the columnar magnetostrictor 51 on the upper housing body 2a side (corresponding to one end face of the columnar magnetostrictor in the present invention) and in which the other end face of the sponge 52a can come into contact with the bias magnet 53a. The sponge 52b is disposed in a state in which one end face of the sponge 52b is in contact with the end face of the columnar magnetostrictor 51 on the vibration transmitter 55 side (corresponding to one end face of the columnar magnetostrictor in the present invention) and in which the other end face of the sponge 52b can come into contact with the bias magnet 53b.

The bias magnet 53a, as described above, is disposed between the sponge 52a and the partition 22 in a state in which it can come into contact with the other end face of the sponge 52a, and the bias magnet 53b is disposed between the sponge 52b and after-described flange 55a in a state in which it can come into contact with the other end face of the sponge 52b. In this case, the bias magnets 53a, 53b apply such a bias magnetic field as to be able to move the columnar magnetostrictor 51 between operating points to effect approximately linear expansion and contraction (vibration) against variation of the magnetic field in the axial direction. Therefore, the columnar magnetostrictor 51 expands to a length corresponding to the operating point to effect approximately linear expansion and contraction with application of the bias magnetic field. The drive coil 54 corresponds to the magnetic field generator in the present invention and, as shown in FIGS. 1 and 2, is disposed so that the center axis of the drive coil 54 becomes coaxial with the center axis of the columnar magnetostrictor 51. The drive coil 54, as shown in FIG. 2, generates the magnetic field on the axis of the drive coil 54 (or on the axis of the columnar magnetostrictor 51) with input of the drive current from the acoustic signal amplifier 3 through the connection cable.

The vibration transmitter 55, as shown in FIG. 1, is integrally constructed with the flange 55a of disc shape, shaft 55b, and tip contact part 55c. The flange 55a, as shown in the same figure, is in contact at the upper end face of the flange 55a with the sponge 53b and in contact at the lower end face of the flange 55a with the springs 56. Each spring 56, as shown in the same figure, is disposed in the interior space of the lower housing body 2b in a state in which one end thereof is in contact with the flange 55a while the other end is in contact with the inner wall of the lower housing body 2b and in which it biases the flange 55a toward the columnar magnetostrictor 51. The shaft 55b is so arranged that the tip contact part 55c is fixed to the distal end face of the shaft 55b, and transmits vibration of flange 55a to the tip contact part 55c. The tip contact part 55c, as shown in the same figure, has the tip end formed in a semispherical shape, as an example, and transmits vibration of the vibration transmitter 55 to the plate body 7 when urged against the plate body 7 (the object in the present invention). As shown in the same figure, therefore, the springs 56 bias the flange 55a so as to integrally couple the flange 55a, bias magnet 53b, sponge 52b, columnar magnetostrictor 51, sponge 52a, and bias magnet 53a and so as to maintain the vibration transmitter 55 in a state in which it can travel back and forth (or can vibrate) along the axial direction of the vibration transmitter 55. In consequence, the vibration transmitter 55 moves away from the partition 22 with expansion of the columnar magnetostrictor 51, and moves toward the partition 22 with contraction of the columnar magnetostrictor 51. As a result, the vibration transmitter 55 (flange 55a) vibrates in the directions along the directions of expansion and contraction of the columnar magnetostrictor 51 in accordance with the expansion and contraction of the columnar magnetostrictor 51.

Next, the overall operation of the pencil type speaker 1 will be described.

In this pencil type speaker 1, the acoustic signal amplifier 3 amplifies an acoustic signal fed through the acoustic signal cable 6 from the outside and supplies the drive current to the drive coil 54. On this occasion, the drive coil 54 applies the magnetic field generated based on the supplied drive current, to the columnar magnetostrictor 51. For this reason, the columnar magnetostrictor 51 expands and contracts in the axial direction according to the applied magnetic field. On this occasion, when the tip contact part 55c is urged against the plate body 7 under such predetermined pressure as to contract the sponges 52a, 52b over the limit for retention of elasticity thereof, the partition 22 functions as a stopper (i.e., inertia mass together with the weights of a human hand and pencil type speaker 1), whereby the sponges 52a, 52b become compressed to function as inelastic plate bodies. Therefore, the vibration with expansion and contraction of the columnar magnetostrictor 51 is transmitted through the sponge 52b, the bias magnet 53b, the flange 55a, the shaft 55b, and the tip contact part 55c to the plate body 7 during this period. In this state, with vibration of the plate body 7, the acoustic signal fed from the outside is outputted as adequately audible sound from the plate body 7.

In the pencil type speaker 1, with application of the bias magnetic field by the bias magnets 53a, 53b, the columnar magnetostrictor 51 is expanded (displaced) to the length to enable approximately linear expansion and contraction. In this case, the columnar magnetostrictor 51 demonstrates greater displacement in the region near the edge of the end faces of the columnar magnetostrictor 51 than displacement in the central part, and thus the end faces of the columnar magnetostrictor 51 are deformed in the conical shape. In this state, when the magnetic field generated based on the drive current is applied to the columnar magnetostrictor 51, the columnar magnetostrictor 51 expands and contracts in the axial direction according to the magnetic field applied. In this case, the end faces of the columnar magnetostrictor 51 are deformed in a deeper conical shape with forward increase in the strength of the applied magnetic field, and deformed in a shallower conical shape with backward increase in the strength of the applied magnetic field. Therefore, the end faces of the columnar magnetostrictor 51 always maintain the conical shape though the depth thereof varies. In consequence, if the columnar magnetostrictor 51 were so arranged that hard and flat members are in contact with the two end faces of the columnar magnetostrictor 51, almost the entire stress due to the expansion of the columnar magnetostrictor 51 must be concentrated on the edge of the end faces of the columnar magnetostrictor 51. On the other hand, in the case of this pencil type speaker 1, the sponges 52a, 52b disposed on the two end faces of the columnar magnetostrictor 51 sufficiently absorb the stress concentrated on the edge in the two end faces of the columnar magnetostrictor 51. With this pencil type speaker 1, therefore, it is feasible to avoid occurrence of breakage of the columnar magnetostrictor 51 due to the concentration of stress on the edge of the end faces of the columnar magnetostrictor 51. Even if breakage occurs, the degree of the breakage can be reduced.

If a foreign body such as dust is attached to an end face of the columnar magnetostrictor 51, the stress due to expansion of the columnar magnetostrictor 51 will be concentrated on the part where the foreign body is attached and on fine unevenness in the end face. In this pencil type speaker 1 on the other hand, the sponges 52a, 52b disposed on the two end faces of the columnar magnetostrictor 51 absorb the stress concentrated on the part where the foreign body is attached and on the fine unevenness in the end face. Therefore, it is feasible to avoid occurrence of breakage of the columnar magnetostrictor 51 due to attachment of the foreign body and the presence of fine unevenness in the end face. Even if breakage occurs, the degree of the breakage can be reduced.

If an external force due to a drop or the like is applied to the tip contact part 55c, the external force can be concentrated on the end faces of the columnar magnetostrictor 51 to break the columnar magnetostrictor 51. In the pencil type speaker 1, however, the sponges 52a, 52b disposed on the two end faces of the columnar magnetostrictor 51 absorb the external force. Therefore, it is feasible to avoid occurrence of breakage of the columnar magnetostrictor 51 due to a drop or the like. Even if breakage occurs, the degree of the breakage can be reduced.

The present invention is by no means limited to the above-described configuration. For example, the above configuration described the configuration with two sponges 52a, 52b, but it is also possible to adopt a configuration with only one of the sponges 52a, 52b. By this configuration, it is also feasible to avoid breakage of the columnar magnetostrictor 51 due to the concentration of stress and external force. Even if breakage occurs, the degree of the breakage can be reduced.

The above described the configuration with the bias magnets 53a, 53b, but it is also possible to adopt a configuration in which at least one of the sponges 52a, 52b is disposed so as to be able to contact at least one end face of the columnar magnetostrictor 51, without provision of the bias magnets 53a, 53b. By this configuration, it is also feasible to avoid breakage of the columnar magnetostrictor 51 due to the concentration of stress and external force. Even if breakage occurs, the degree of the breakage can be reduced.

The above described the configuration employing the sponges 52a, 52b as the elastic member according to the present invention, but it is also possible to adopt a configuration using rubber or the like, instead of the sponges. By this configuration, it is also feasible to avoid the breakage of the columnar magnetostrictor 51 due to the concentration of stress and external force on the columnar magnetostrictor 51. Even if breakage occurs, the degree of the breakage can be reduced.

The above described the pencil type speaker 1 in the configuration with one columnar magnetostrictor 51, but the number of columnar magnetostrictor 51 is not limited to 1, and may be two or more. It is a matter of course that in this configuration a bias magnet and sponge may be optionally disposed between columnar magnetostrictors 51.

Furthermore, the above described the example of application of the actuator according to the present invention to the pencil type speaker 1, but it is commonly and generally applicable to actuators for actuating an object, without having to be limited to the application to the acoustic equipment such as the pencil type speaker.

1. An actuator comprising:
a columnar magnetostrictor one end of which is defined as a fixed end and an other end of which is defined as a free end to expand and contract along an axial direction;
a magnetic field generator for generating a magnetic field to expand and contract the columnar magnetostrictor by a drive current; and
an elastic member disposed on at least one end face of the columnar magnetostrictor,
the actuator being arranged to be able to actuate an object with expansion and contraction of the columnar magnetostrictor.

2. The actuator according to claim 1, wherein the elastic member is disposed on each of two end faces of the columnar magnetostrictor.
